(19) United States
(12) Patent Application Publication
(10) Pub. No.: US 2025/0007466 A1
(43) Pub. Date: Jan. 2, 2025

(54) AMPLIFIER CIRCUIT

(71) Applicant: Murata Manufacturing Co., Ltd., Nagaokakyo-shi (JP)

(72) Inventor: Ikumi TOKUDA, Nagaokakyo-shi (JP)

(73) Assignee: Murata Manufacturing Co., Ltd., Nagaokakyo-shi (JP)

(21) Appl. No.: 18/749,640

(22) Filed: Jun. 21, 2024

(30) Foreign Application Priority Data
Jun. 28, 2023 (JP) 2023-105818

(51) Int. Cl. H03F 1/02; H03F 1/32; H03F 3/24

(52) U.S. Cl. CPC H03F 1/0288; H03F 1/32; H03F 3/245; H03F 2200/451

(57) ABSTRACT

An amplifier circuit includes a carrier amplifier, a peak amplifier, a phase shift line, a power combiner that combines radio frequency signals input to a first terminal and a second terminal to obtain a combined radio frequency signal and outputs the combined radio frequency signal from a third terminal, and an impedance element that is a resistor element or a capacitor. The carrier amplifier is connected between a signal input terminal and the first terminal, the peak amplifier is connected between the signal input terminal and a first end of the phase shift line, a second end of the phase shift line is connected to the second terminal, a signal output terminal is connected to the third terminal, a first end of the impedance element is connected to the second terminal, and a second end of the impedance element is connected to the signal output terminal.

### CROSS-REFERENCE TO RELATED APPLICATION

The present application claims priority to Japanese patent application JP 2023-105818, filed Jun. 28, 2023, the entire contents of which are incorporated herein by reference.

### BACKGROUND

In a Doherty amplifier circuit, when the power level of an input signal becomes high, the peak amplifier operates to adjust the load impedance of the output end of the carrier amplifier. This improves the efficiency and the linearity of the Doherty amplifier circuit.

### SUMMARY

An amplifier circuit according to an aspect of the present disclosure includes an input terminal and an output terminal; a carrier amplifier and a peak amplifier; a first phase shift circuit; a power combiner that combines radio frequency signals input to a first terminal and a second terminal to obtain a combined radio frequency signal and outputs the combined radio frequency signal from a third terminal; and an impedance element. The carrier amplifier is connected between the input terminal and the first terminal; the peak amplifier is connected between the input terminal and a first end of the first phase shift circuit; a second end of the first phase shift circuit is connected to the second terminal; the output terminal is connected to the third terminal; a first end of the impedance element is connected to the second terminal; and a second end of the impedance element is connected to the output terminal.

Also, an amplifier circuit according to an aspect of the present disclosure includes an input terminal and an output terminal; a carrier amplifier and a peak amplifier; a first phase shift circuit; a power combiner that combines radio frequency signals input to a first terminal and a second terminal to obtain a combined radio frequency signal and outputs the combined radio frequency signal from a third terminal; and an impedance element. The carrier amplifier is connected between the input terminal and the first terminal; the peak amplifier is connected between the input terminal and a first end of the first phase shift circuit; a second end of the first phase shift circuit is connected to the second terminal; the output terminal is connected to the third terminal; a first end of the impedance element is connected to the first terminal; and a second end of the impedance element is connected to the output terminal.

Also, an amplifier circuit according to an aspect of the present disclosure includes an input terminal and an output terminal; a carrier amplifier and a peak amplifier; a first phase shift circuit; a power combiner that combines radio frequency signals input to a first terminal and a second terminal to obtain a combined radio frequency signal and outputs the combined radio frequency signal from a third terminal; and an impedance element. The carrier amplifier is connected between the input terminal and the first terminal; the peak amplifier is connected between the input terminal and a first end of the first phase shift circuit; a second end of the first phase shift circuit is connected to the second terminal; the output terminal is connected to the third terminal; a first end of the impedance element is connected to the second terminal; and a second end of the impedance element is connected to the first terminal.

### BRIEF DESCRIPTION OF THE DRAWINGS

FIG. 1 is a circuit diagram of an amplifier circuit, a radio frequency circuit, and a communication device according to a first example;

FIG. 2 is a circuit diagram of an amplifier circuit according to a comparative example;

FIG. 3 is a graph showing characteristics of the gain and the load impedance of each of the amplifier circuits according to the example and the comparative example;

FIG. 4 is a circuit diagram of an amplifier circuit according to a second example;

FIG. 5 is a circuit diagram of an amplifier circuit according to a third example;

FIG. 6 is a circuit diagram of an amplifier circuit according to a fourth example; and

FIG. 7 is a circuit diagram of an amplifier circuit according to a fifth example.

### DETAILED DESCRIPTION

In the case of the Doherty amplifier circuit, while the peak amplifier is in operation, a signal obtained by combining output signals of the carrier amplifier and the peak amplifier is output from the carrier amplifier. However, when the load impedance of the output end of the carrier amplifier is not ideal, a part of the output signal of the peak amplifier is not combined with the output signal of the carrier amplifier and may leak to the output terminal of the Doherty amplifier circuit. As a result, power efficiency of the Doherty amplifier circuit decreases, gain linearity is reduced, and signal distortion may occur.

The present disclosure is made to solve at least the above-described situation, and one aspect of the present disclosure is to provide a Doherty amplifier circuit that can improve power efficiency and reduce signal distortion.

The present disclosure makes it possible to provide a Doherty amplifier circuit that can improve power efficiency and reduce signal distortion.

Exemplary embodiments of the present disclosure are described below in detail. Each of the exemplary embodiments described below represents a general or specific example. Values, shapes, materials, components, and layout and connection configurations of the components described in the exemplary embodiments below are just examples and are not intended to limit the present disclosure. Among components described in the examples and the variations below, components not recited in independent claims are optional components.

Also, sizes or ratios of sizes of components illustrated in the drawings are not necessarily accurate. In the drawings, the same reference number is assigned to substantially the same components, and overlapping descriptions of those components are omitted or simplified.

Also, in the descriptions below, terms such as “parallel” and “perpendicular” indicating relationships between elements, terms such as “rectangular” indicating shapes of elements, and numerical ranges do not only indicate their exact meanings but may also indicate substantially equivalent ranges that vary by, for example, about a few percent.

In circuit configurations of the present disclosure, “connected” not only indicates that circuit elements are directly connected to each other with a connection terminal and/or a wire conductor but also indicates that the circuit elements are electrically connected to each other via another circuit element. Also, “connected between A and B” indicates that a component is disposed between A and B and connected to both of A and B. Specifically, “connected between A and B” not only indicates that a component is connected in series with A and B in a path connecting A and B but also indicates that a component is connected in parallel with (in shunt connection with) A and B at a position between the path and a ground.

Furthermore, in the present disclosure, “signal path” indicates a transmission line that is constituted by, for example, a wire for transmitting a radio frequency signal, an electrode directly connected to the wire, and a terminal directly connected to the wire or the electrode.

In circuit connection configurations of the present disclosure, “component (element) A is disposed in series with path B” means that each of a signal input end and a signal output end of the component (element) A is connected to one of a wire, an electrode, and a terminal constituting the path B. Also, “multiple paths are connected in parallel with each other” means that ends of the multiple paths are connected to the same wire, electrode, or terminal.

### Exemplary Embodiment

### 1. Circuit Configurations of Amplifier Circuit 10, Radio Frequency Circuit 1, and Communication Device 4

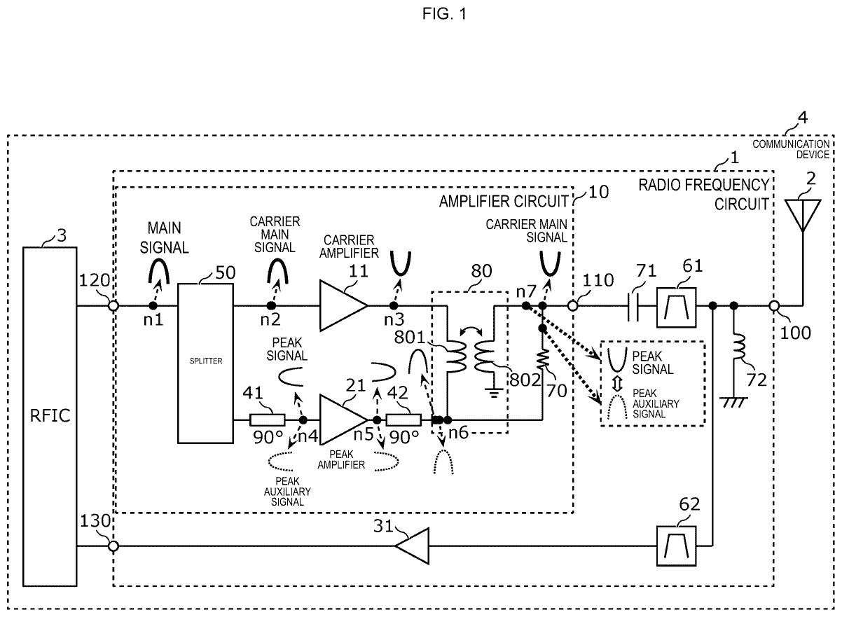

Circuit configurations of an amplifier circuit 10, a radio frequency circuit 1, and a communication device 4 according to a first example of the present exemplary embodiment are described with reference to FIG. 1. FIG. 1 is a circuit diagram of the amplifier circuit 10, the radio frequency circuit 1, and the communication device 4 according to the first example.

### 1.1 Circuit Configuration of Communication Device 4

First, a circuit configuration of the communication device 4 is described. As illustrated in FIG. 1, the communication device 4 according to the first example includes the radio frequency circuit 1, an antenna 2, and a radio frequency signal processing circuit (RFIC) 3.

The radio frequency circuit 1 transmits radio frequency signals between the antenna 2 and the RFIC 3. The detailed circuit configuration of the radio frequency circuit 1 is described later.

The antenna 2 is connected to an antenna connection terminal 100 of the radio frequency circuit 1, transmits a radio frequency signal output from the radio frequency circuit 1, receives a radio frequency signal from the outside, and outputs the received radio frequency signal to the radio frequency circuit 1.

The RFIC 3 is an example of a signal processing circuit that processes a radio frequency signal and is connected to a signal input terminal 120 and a signal output terminal 130 of the radio frequency circuit 1. Specifically, the RFIC 3 performs signal processing, such as down-converting, on a reception signal input via a reception path of the radio frequency circuit 1 and outputs a reception signal generated by the signal processing to a baseband signal processing circuit (BBIC). Also, the RFIC 3 performs signal processing, such as up-converting, on a transmission signal input from the BBIC and outputs a transmission signal generated by the signal processing to a transmission path of the radio frequency circuit 1. The RFIC 3 includes a control unit that controls circuit components of the radio frequency circuit 1. Some or all of the functions of the control unit of the RFIC 3 may be provided outside of the RFIC 3 and may be implemented by, for example, a component in the BBIC or the radio frequency circuit 1.

The RFIC 3 also has a function of a control unit for controlling a power supply voltage and a bias voltage (or a bias current) supplied to each amplifier of the radio frequency circuit 1. Specifically, the RFIC 3 outputs a control signal to the radio frequency circuit 1. A power supply voltage and a bias voltage (or a bias current) controlled by the control signal are supplied to each amplifier of the radio frequency circuit 1.

In the communication device 4 according to this example, the antenna 2 is not an essential component.

### 1.2 Circuit Configuration of Radio Frequency Circuit 1

Next, a circuit configuration of the radio frequency circuit 1 is described. As illustrated in FIG. 1, the radio frequency circuit 1 includes the amplifier circuit 10, filters 61 and 62, a low-noise amplifier 31, a capacitor 71, an inductor 72, the antenna connection terminal 100, the signal input terminal 120, and the signal output terminal 130.

The filter 61 is connected between the signal output terminal 110 and the antenna connection terminal 100 and passes a transmission signal in a band A among transmission signals amplified by the amplifier circuit 10. The filter 62 is connected between the low-noise amplifier 31 and the antenna connection terminal 100 and passes a reception signal in a reception band corresponding to the band A among reception signals received by the antenna 2.

The filters 61 and 62 may constitute a duplexer that transmits and receives signals in the band A or may be implemented by a single filter that transmits signals according to time division duplex (TDD). When the filters 61 and 62 are implemented by a single filter for TDD, a switch for switching between transmission and reception is provided at least before or after the single filter.

The low-noise amplifier 31 is connected between the filter 62 and the signal output terminal 130, amplifies a reception signal in the band A, and outputs the amplified reception signal to the RFIC 3.

The capacitor 71 is a circuit element for impedance matching and is disposed in series between the signal output terminal 110 and the filter 61. The capacitor 71 may instead be connected between a ground and a path connecting the signal output terminal 110 to the filter 61 (i.e., shunt connection) or may be omitted.

The inductor 72 is a circuit element for impedance matching and is connected between the ground and a path connecting the filter 61 to the antenna connection terminal 100 (shunt connection). The inductor 72 may instead be disposed in series between the filter 61 and the antenna connection terminal 100 or may be omitted.

The radio frequency circuit 1 may also include a transmitter circuit that transmits a transmission signal in a band B different from the band A to the antenna 2 and a receiver circuit that transmits, to the RFIC 3, a reception signal in the band B received from the antenna 2. Furthermore, the radio frequency circuit 1 may be configured to transmit and receive radio frequency signals in three or more bands.

### 1.3 Circuit Configuration of Amplifier Circuit 10 According to First Example

Next, a circuit configuration of the amplifier circuit 10 is described in detail.

As illustrated in FIG. 1, the amplifier circuit 10 includes the signal input terminal 120, the signal output terminal 110, a carrier amplifier 11, a peak amplifier 21, phase shift lines 41 and 42, a splitter 50, a transformer 80, and a resistor element 70.

The signal input terminal 120 is an example of an input terminal and is connected to the RFIC 3. The signal output terminal 110 is an example of an output terminal and is connected to the antenna connection terminal 100 via the capacitor 71 and the filter 61. Here, each of the signal input terminal 120, the signal output terminal 110, and the antenna connection terminal 100 may be a metal conductor, such as a metal electrode or a metal bump, or a point on a metal wire.

The carrier amplifier 11 amplifies a radio frequency signal that is input to the carrier amplifier 11. The carrier amplifier 11 is, for example, a class A (or class AB) amplifier circuit that can amplify signals of all power levels input to the carrier amplifier 11. Particularly, the carrier amplifier 11 can efficiently perform amplification in the low power region and the medium power region. The carrier amplifier 11 is, for example, an inverting amplifier that inverts the phase of an input signal and outputs a phase-inverted signal. The input end of the carrier amplifier is connected to the signal input terminal 120 via the splitter 50, and the output end of the carrier amplifier is connected to the transformer 80.

The peak amplifier 21 amplifies a radio frequency signal input to the peak amplifier 21. The peak amplifier 21 is, for example, a class C amplifier circuit that can perform amplification in a region in which the power level of a signal input to the peak amplifier 21 is high. For example, a bias voltage lower than the bias voltage applied to the amplifier transistor of the carrier amplifier 11 is applied to the amplifier transistor of the peak amplifier 21. With this configuration, the output impedance decreases as the power level of a signal input to the peak amplifier 21 increases. This enables the peak amplifier 21 to perform low-distortion amplification in the high power region. The peak amplifier 21 is, for example, an inverting amplifier that inverts the phase of an input signal and outputs a phase-inverted signal. The input end of the peak amplifier 21 is connected to the phase shift line 41, and the output end of the peak amplifier 21 is connected to the phase shift line 42.

Each of the carrier amplifier 11 and the peak amplifier 21 includes an amplifier transistor. The amplifier transistor is, for example, a bipolar transistor, such as a heterojunction bipolar transistor (HBT), or a field-effect transistor, such as a metal-oxide-semiconductor field effect transistor (MOSFET).

The phase shift line 42 is an example of a first phase shift circuit and is, for example, a quarter wavelength transmission line. The phase shift line 42 delays the phase of a radio frequency signal input from its first end by 90° (a quarter wavelength) and outputs the phase-delayed radio frequency signal from its second end. The phase shift line 42 (the first phase shift circuit) does not have to be in the form of a phase shift line. For example, the phase shift line 42 may be an inductor element, or a low pass filter including an inductor and a capacitor, that is disposed in series in a path connecting the peak amplifier 21 to the transformer 80. The first end of the phase shift line 42 is connected to the output end of the peak amplifier 21, and the second end of the phase shift line 42 is connected to the transformer 80.

The phase shift line 41 is an example of a second phase shift circuit and is, for example, a quarter wavelength transmission line. The phase shift line 41 delays the phase of a radio frequency signal input from its first end by 90° (a quarter wavelength) and outputs the phase-delayed radio frequency signal from its second end. The phase shift line 41 (the second phase shift circuit) does not have to be in the form of a phase shift line. For example, the phase shift line 41 may be an inductor element, or a low pass filter including an inductor and a capacitor, that is disposed in series in a path connecting the splitter 50 to the peak amplifier 21. The first end of the phase shift line 41 is connected to the signal input terminal 120 via the splitter 50, and the second end of the phase shift line 41 is connected to the input end of the peak amplifier 21.

Each of the phase shift lines 41 and 42 is not necessarily configured to delay the phase of an input radio frequency signal in the band A by 90°, and may be any type of circuit that delays the phase of a radio frequency signal in the band A by a degree within 90°+20°.

The transformer 80 is an example of a power combiner and includes a first terminal, a second terminal, and a third terminal. The transformer 80 combines radio frequency signals input to the first terminal and the second terminal to obtain a combined radio frequency signal, and outputs the combined radio frequency signal from the third terminal. The transformer 80 includes a coil 801 (a first coil) and a coil 802 (a second coil) that are electromagnetically coupled to each other. A first end of the coil 801 is connected to the output end of the carrier amplifier 11 via the first terminal, and a second end of the coil 801 is connected to the second end of the phase shift line 42 via the second terminal. A first end of the coil 802 is connected to the signal output terminal 110 via the third terminal, and a second end of the coil 802 is connected to the ground. Alternatively, the first end of the coil 801 may be referred to as the first terminal, the second end of the coil 801 may be referred to as the second terminal, and the first end of the coil 802 may be referred to as the third terminal.

The splitter 50 is an example of a power splitter and is connected between the signal input terminal 120 and the input ends of the carrier amplifier 11 and the peak amplifier 21. The splitter 50 includes a fourth terminal, a fifth terminal, and a sixth terminal. The splitter 50 distributes the power of a radio frequency signal input to the fourth terminal between two radio frequency signals at a predetermined distribution ratio, outputs one of the two radio frequency signals from the fifth terminal, and outputs the other one of the two radio frequency signals from the sixth terminal. The fourth terminal is connected to the signal input terminal 120, the fifth terminal is connected to the input end of the carrier amplifier 11, and the sixth terminal is connected to the first end of the phase shift line 41.

The resistor element 70 is an example of a first resistor element and is also an example of an impedance element. A first end of the resistor element 70 is connected to the second end (a second terminal) of the coil 801, and a second end of the resistor element 70 is connected to the signal output terminal 110. The resistor element 70 is disposed in series in a bypass route different from a path connecting the second terminal, the coils 801 and 802, and the signal output terminal 110.

Next, an operation of a Doherty amplifier circuit including a carrier amplifier and a peak amplifier is described with reference to an amplifier circuit 500 according to a comparative example.

A Doherty amplifier circuit achieves high efficiency by using multiple amplifiers as a carrier amplifier and a peak amplifier. The carrier amplifier in the Doherty amplifier circuit operates regardless of whether the power of a radio frequency signal (input) is low or high. The peak amplifier in the Doherty amplifier circuit operates primarily when the power of a radio frequency signal (input) is high. Accordingly, when the input power of a radio frequency signal is low, the radio frequency signal is amplified primarily by the carrier amplifier; and when the input power of a radio frequency signal is high, the radio frequency signal is amplified by the carrier amplifier and the peak amplifier, and amplified radio frequency signals are combined. With this operation, in the Doherty amplifier circuit, the load impedance seen from the carrier amplifier increases in the low output power region, and the efficiency at the low output power improves. Also, the load impedance seen from the carrier amplifier decreases in the high output power region, and the linearity at the high output power improves.

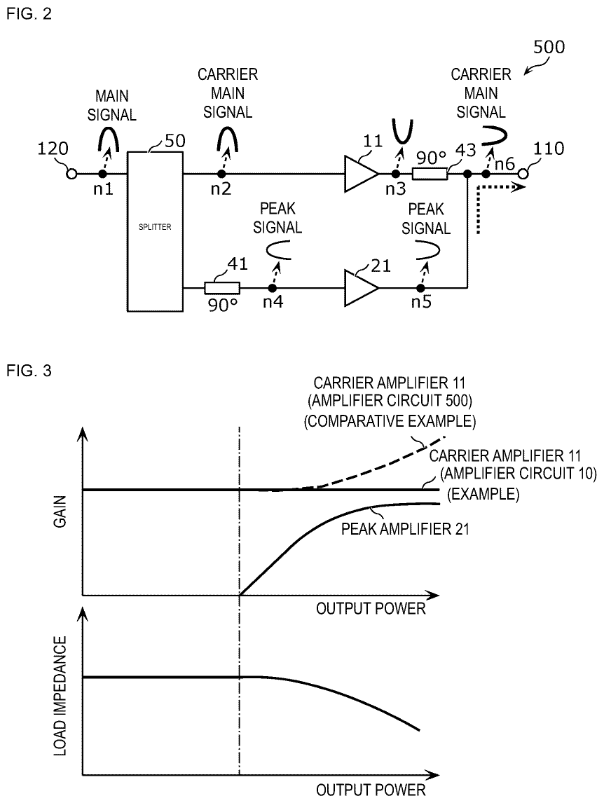

FIG. 2 is a circuit diagram of the amplifier circuit 500 according to the comparative example. The amplifier circuit 500 illustrated in FIG. 2 includes a signal input terminal 120, a signal output terminal 110, a carrier amplifier 11, a peak amplifier 21, phase shift lines 41 and 43, and a splitter 50. The amplifier circuit 500 according to the comparative example differs from the amplifier circuit 10 according to the first example in that the phase shift line 43 is added in place of the phase shift line 42, and the transformer 80 is omitted.

When the carrier amplifier 11 and the peak amplifier 21 are in operation (ON) (when a large signal is input), the load impedance of the carrier amplifier 11 is converted by the phase shift line 43 and becomes smaller than the load impedance of the carrier amplifier 11 observed when the carrier amplifier 11 is in operation (ON) and the peak amplifier 21 is not in operation (OFF) (when a small signal is input). Thus, when a large signal is input, the carrier amplifier 11 and the peak amplifier 21 operate, and a high power signal can be output.

When the carrier amplifier 11 is in operation (ON) and the peak amplifier 21 is not in operation (OFF) (when a small signal is input), the load impedance of the peak amplifier 21 becomes open-circuited, and the load impedance of the carrier amplifier 11 observed when a small signal is input becomes higher than that observed when a large signal is input. Thus, when a small signal is input, the load impedance of the carrier amplifier 11 increases, and the amplifier circuit 500 can operate highly efficiently.

However, when the carrier amplifier 11 and the peak amplifier 21 are in operation (when a large signal is input), because the carrier amplifier 11 has finite impedance and does not have ideal impedance, a part of the output signal of the peak amplifier 21 tends to not be combined with the output signal of the carrier amplifier 11 and may leak to the signal output terminal 110 by itself. This may reduce the power efficiency of the amplifier circuit 500. Also, this may reduce gain linearity and thereby cause signal distortion.

In contrast, in the amplifier circuit 10 according to this example, because a bypass route having the resistor element 70 is provided, the leakage of a signal from the peak amplifier 21 via the transformer 80 to the signal output terminal 110 is offset by a signal transmitted through the bypass route. This in turn makes it possible to reduce the distortion of the output signal resulting from the operation of the peak amplifier 21.

A state of the amplifier circuit 10 according to this example is described in detail below with reference to FIG. 1.

As illustrated in FIG. 1, a radio frequency main signal is first input from the signal input terminal 120. Here, it is assumed that the phase of the radio frequency main signal is 0° at a node n1 on a path connecting the signal input terminal 120 to the splitter 50. It is also assumed that the power of the radio frequency main signal is distributed by the splitter 50 to a carrier main signal output to the carrier amplifier 11 and a peak signal and a peak auxiliary signal output to the peak amplifier 21. At a node n2 on a path connecting the splitter 50 to the carrier amplifier 11, the phase of the carrier main signal is unchanged at 0°. On the other hand, at a node n4 on a path connecting the phase shift line 41 to the peak amplifier 21, the phases of the peak signal and the peak auxiliary signal are delayed by the phase shift line 41 by 90° to become −90°.

Next, the phase of the carrier main signal is inverted by the carrier amplifier 11 and becomes −180° at a node n3 on a path connecting the output end of the carrier amplifier 11 to the coil 801. On the other hand, the phases of the peak signal and the peak auxiliary signal are inverted by the peak amplifier 21, become −270° at a node n5 corresponding to the output end of the peak amplifier 21, and are delayed by the phase shift line 42 by 90° to become 0° at a node n6 corresponding to the second end of the coil 801.

Next, the peak signal and the peak auxiliary signal amplified by the peak amplifier 21 diverge at the second end of the coil 801. The peak signal reaches, via the coils 801 and 802, a node n7 on a path connecting the coil 802 to the signal output terminal 110. The peak auxiliary signal reaches the node n7 via the resistor element 70. Here, because the peak signal is transmitted from the second end of the coil 801 to the first end of the coil 802, the phase of the peak signal is inverted and becomes −180° at the node n7. On the other hand, because the peak auxiliary signal passes through the resistor element 70, the phase of the peak auxiliary signal does not shift and is 0° at the node n7. That is, because the phases of the peak signal and the peak auxiliary signal are opposite to each other at the node n7, the peak signal and the peak auxiliary signal substantially offset each other at the node n7.

The resistance value of the resistor element 70 is determined such that the amplitudes of the peak signal and the peak auxiliary signal become substantially the same at the node n7.

This makes it possible to prevent a part of the output signal of the peak amplifier 21 from leaking to the signal output terminal 110 by itself.

FIG. 3 is a graph showing characteristics of the gain and the load impedance of each of the amplifier circuits according to the first example and the comparative example. The upper part of FIG. 3 shows the gains of the carrier amplifier 11 and the peak amplifier 21 in relation to the output power of the amplifier circuits. The lower part of FIG. 3 shows the load impedance at the output end of the carrier amplifier 11.

As shown in FIG. 3, the peak amplifier 21 is turned on in a region in which the output power of each amplifier circuit is high. When the peak amplifier 21 is turned on, the load impedance of the carrier amplifier 11 decreases, and the carrier amplifier 11 can output a high power signal.

Also, in the amplifier circuit 500 according to the comparative example, because the output signal of the peak amplifier 21 leaks to the signal output terminal 110 by itself, the gain of the amplifier circuit 500 increases as the output power increases. As a result, gain linearity is reduced, and signal distortion increases.

In contrast, with the amplifier circuit 10 according to this example, it is possible to prevent the output signal of the peak amplifier 21 from leaking to the signal output terminal 110 by itself, and the gain of the amplifier circuit 10 becomes substantially the same as the gain of the carrier amplifier 11. This in turn makes it possible to keep the gain constant and thereby makes it possible to reduce signal distortion.

### 1.4 Circuit Configuration of Amplifier Circuit 10A According to Second Example

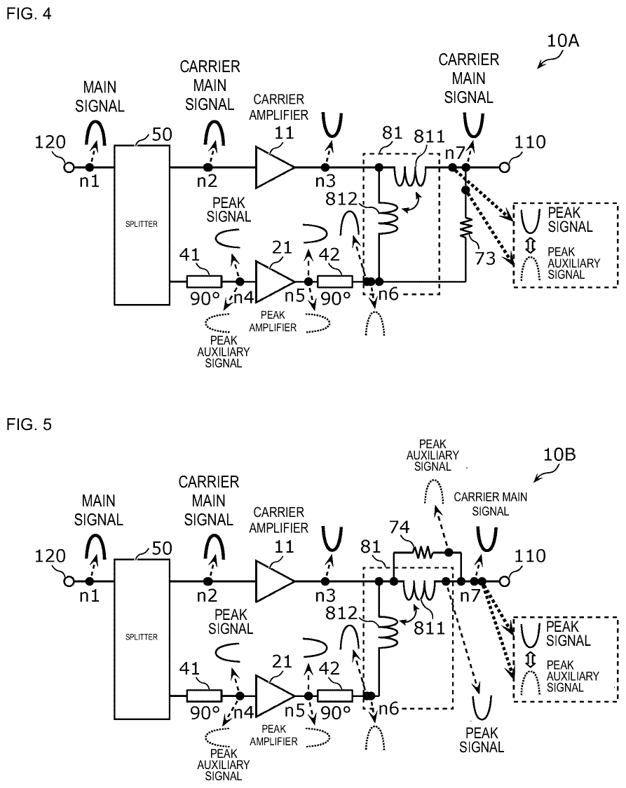

Next, a circuit configuration of an amplifier circuit 10A according to a second example is described in detail. FIG. 4 is a circuit diagram of the amplifier circuit 10A according to the second example. As illustrated in FIG. 4, the amplifier circuit 10A includes a signal input terminal 120, a signal output terminal 110, a carrier amplifier 11, a peak amplifier 21, phase shift lines 41 and 42, a splitter 50, a transformer 81, and a resistor element 73. The amplifier circuit 10A according to this example differs from the amplifier circuit 10 according to the first example in the configuration of the transformer 81. Below, descriptions of configurations of the amplifier circuit 10A of this example identical to those of the amplifier circuit 10 of the first example are omitted, and different configurations are mainly described.

The input end of the carrier amplifier 11 is connected to the signal input terminal 120 via the splitter 50, and the output end of the carrier amplifier 11 is connected to the transformer 81. The input end of the peak amplifier 21 is connected to the phase shift line 41, and the output end of the peak amplifier 21 is connected to the phase shift line 42.

The phase shift line 42 is an example of a first phase shift circuit and is, for example, a quarter wavelength transmission line. The first end of the phase shift line 42 is connected to the output end of the peak amplifier 21, and the second end of the phase shift line 42 is connected to the transformer 81. The first end of the phase shift line 41 is connected to the signal input terminal 120 via the splitter 50, and the second end of the phase shift line 41 is connected to the input end of the peak amplifier 21.

The transformer 81 is an example of a power combiner and includes a first terminal, a second terminal, and a third terminal. The transformer 81 combines radio frequency signals input to the first terminal and the second terminal to obtain a combined radio frequency signal, and outputs the combined radio frequency signal from the third terminal. The transformer 81 includes a coil 811 (a second coil) and a coil 812 (a first coil) that are electromagnetically coupled to each other. A first end of the coil 811 and a first end of the coil 812 are connected to the output end of the carrier amplifier 11 via the first terminal. A second end of the coil 811 is connected to the second end of the phase shift line 42 via the second terminal. The first end of the coil 812 is connected to the signal output terminal 110 via the third terminal. Alternatively, the first end of the coil 811 and the first end of the coil 812 may be referred to as the first terminal, the second end of the coil 812 may be referred to as the second terminal, and the second end of the coil 811 may be referred to as the third terminal.

Instead of the transformer 81, the power combiner may be a transmission line transformer including two transmission lines that are electromagnetically coupled to each other.

The resistor element 73 is an example of a first resistor element and is also an example of an impedance element. A first end of the resistor element 73 is connected to the second end (the second terminal) of the coil 812, and a second end of the resistor element 73 is connected to the signal output terminal 110. The resistor element 73 is disposed in series in a bypass route different from a path connecting the second terminal, the coils 812 and 811, and the signal output terminal 110.

In the amplifier circuit 10A according to this example, because a bypass route having the resistor element 73 is provided, the leakage of a signal from the peak amplifier 21 via the transformer 81 to the signal output terminal 110 is offset by a signal transmitted through the bypass route. This in turn makes it possible to reduce the distortion of the output signal resulting from the operation of the peak amplifier 21.

A state of the amplifier circuit 10A according to this example is described in detail below with reference to FIG. 4.

As illustrated in FIG. 4, a radio frequency main signal is first input from the signal input terminal 120. Here, it is assumed that the phase of the radio frequency main signal is 0° at a node n1 on a path connecting the signal input terminal 120 to the splitter 50. It is also assumed that the power of the radio frequency main signal is distributed by the splitter 50 to a carrier main signal output to the carrier amplifier 11 and a peak signal and a peak auxiliary signal output to the peak amplifier 21. At a node n2 on a path connecting the splitter 50 to the carrier amplifier 11, the phase of the carrier main signal is unchanged at 0°. On the other hand, at a node n4 on a path connecting the phase shift line 41 to the peak amplifier 21, the phases of the peak signal and the peak auxiliary signal are delayed by the phase shift line 41 by 90° to become −90°.

Next, the phase of the carrier main signal is inverted by the carrier amplifier 11 and becomes −180° at a node n3 on a path connecting the output end of the carrier amplifier 11 to the coil 811. On the other hand, the phases of the peak signal and the peak auxiliary signal are inverted by the peak amplifier 21, become −270° at a node n5 corresponding to the output end of the peak amplifier 21, and are delayed by the phase shift line 42 by 90° to become 0° at a node n6 corresponding to the second end of the coil 812.

Next, the peak signal and the peak auxiliary signal amplified by the peak amplifier 21 diverge at the second end of the coil 812. The peak signal reaches, via the coils 812 and 811, a node n7 on a path connecting the coil 811 to the signal output terminal 110. The peak auxiliary signal reaches the node n7 via the resistor element 73. Here, because the peak signal is transmitted from the second end of the coil 812 to the second end of the coil 811, the phase of the peak signal is inverted and becomes −180° at the node n7. On the other hand, because the peak auxiliary signal passes through the resistor element 73, the phase of the peak auxiliary signal does not shift and is 0° at the node n7. That is, because the phases of the peak signal and the peak auxiliary signal are opposite to each other at the node n7, the peak signal and the peak auxiliary signal substantially offset each other at the node n7.

The resistance value of the resistor element 73 is determined such that the amplitudes of the peak signal and the peak auxiliary signal become substantially the same at the node n7.

This makes it possible to prevent a part of the output signal of the peak amplifier 21 from leaking to the signal output terminal 110 by itself. Thus, it is possible to provide the amplifier circuit 10A having improved power efficiency and configured to improve gain linearity and reduce signal distortion.

### 1.5 Circuit Configuration of Amplifier Circuit 10B According to Third Example

Next, a circuit configuration of an amplifier circuit 10B according to a third example is described in detail. FIG. 5 is a circuit diagram of the amplifier circuit 10B according to the third example. As illustrated in FIG. 5, the amplifier circuit 10B includes a signal input terminal 120, a signal output terminal 110, a carrier amplifier 11, a peak amplifier 21, phase shift lines 41 and 42, a splitter 50, a transformer 81, and a resistor element 74. The amplifier circuit 10B according to this example differs from the amplifier circuit 10A according to the second example in the connection configuration of the resistor element 74. Below, descriptions of configurations of the amplifier circuit 10B of this example identical to those of the amplifier circuit 10A of the second example are omitted, and different configurations are mainly described.

The resistor element 74 is an example of a first resistor element and is also an example of an impedance element. A first end of the resistor element 74 is connected to the first end of the coil 811 and the first end (the first terminal) of the coil 812, and a second end of the resistor element 74 is connected to the signal output terminal 110. The resistor element 74 is connected in parallel with the coil 811.

In the amplifier circuit 10B according to this example, because a bypass route having the resistor element 74 is provided, the leakage of a signal from the peak amplifier 21 via the coils 812 and 811 to the signal output terminal 110 is offset by a signal transmitted through the bypass route. This in turn makes it possible to reduce the distortion of the output signal resulting from the operation of the peak amplifier 21.

A state of the amplifier circuit 10B according to this example is described in detail below with reference to FIG. 5.

As illustrated in FIG. 5, a radio frequency main signal is first input from the signal input terminal 120. Here, it is assumed that the phase of the radio frequency main signal is 0° at a node n1 on a path connecting the signal input terminal 120 to the splitter 50. It is also assumed that the power of the radio frequency main signal is distributed by the splitter 50 to a carrier main signal output to the carrier amplifier 11 and a peak signal and a peak auxiliary signal output to the peak amplifier 21. At a node n2 on a path connecting the splitter 50 to the carrier amplifier 11, the phase of the carrier main signal is unchanged at 0°. On the other hand, at a node n4 on a path connecting the phase shift line 41 to the peak amplifier 21, the phases of the peak signal and the peak auxiliary signal are delayed by the phase shift line 41 by 90° to become −90°.

Next, the phase of the carrier main signal is inverted by the carrier amplifier 11 and becomes −180° at a node n3 on a path connecting the output end of the carrier amplifier 11 to the coil 811. On the other hand, the phases of the peak signal and the peak auxiliary signal are inverted by the peak amplifier 21, become −270° at a node n5 corresponding to the output end of the peak amplifier 21, and are delayed by the phase shift line 42 by 90° to become 0° at a node n6 corresponding to the second end of the coil 812.

Next, the peak signal and the peak auxiliary signal amplified by the peak amplifier 21 diverge at a connection point between the first end of the coil 812 and the first end of the coil 811. The peak signal reaches, via the coils 812 and 811, a node n7 on a path connecting the coil 811 to the signal output terminal 110. The peak auxiliary signal reaches the node n7 via the coil 812 and the resistor element 74. Here, because the peak signal passes through the coils 812 and 811 electromagnetically coupled to each other, the phase of the peak signal is inverted and becomes −180° at the node n7. On the other hand, because the peak auxiliary signal passes through the coil 812 and the resistor element 74 not electromagnetically coupled to each other, the phase of the peak auxiliary signal does not shift and is 0° at the node n7. That is, because the phases of the peak signal and the peak auxiliary signal are opposite to each other at the node n7, the peak signal and the peak auxiliary signal substantially offset each other at the node n7.

The resistance value of the resistor element 74 is determined such that the amplitudes of the peak signal and the peak auxiliary signal become substantially the same at the node n7.

This makes it possible to prevent a part of the output signal of the peak amplifier 21 from leaking to the signal output terminal 110 by itself. Thus, it is possible to provide the amplifier circuit 10B having improved power efficiency and configured to improve gain linearity and reduce signal distortion.

Here, in the amplifier circuit 10B according to this example, the resistor element 74 may be replaced with a first capacitor. The first capacitor is an example of an impedance element. A first end of the first capacitor is connected to the first end of the coil 811 and the first end of the coil 812 (the first terminal), and a second end of the first capacitor is connected to the signal output terminal 110. The first capacitor is connected in parallel with the coil 811.

This makes it possible to prevent a part of the output signal of the peak amplifier 21 from leaking to the signal output terminal 110 by itself. Thus, it is possible to provide the amplifier circuit 10B having improved power efficiency and configured to improve gain linearity and reduce signal distortion.

### 1.6 Circuit Configuration of Amplifier Circuit 10C According to Fourth Example

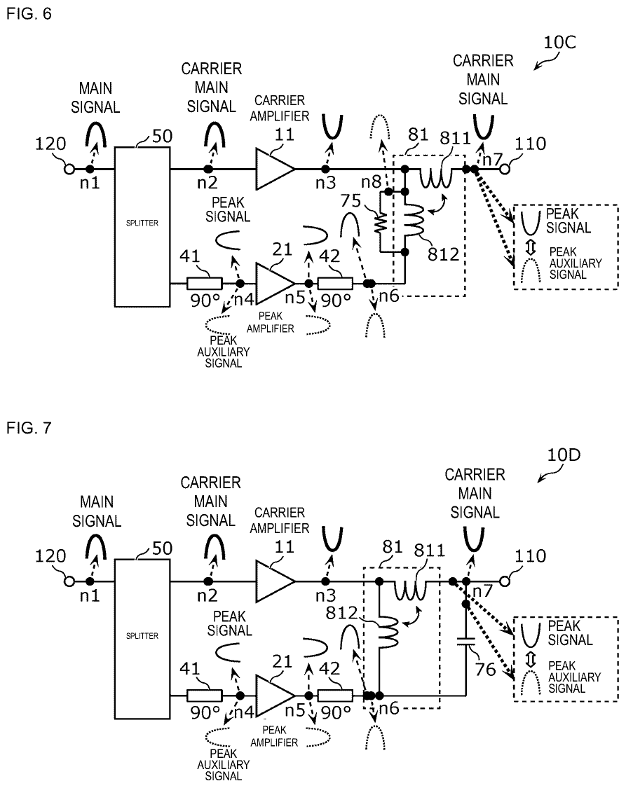

Next, a circuit configuration of an amplifier circuit 10C according to a fourth example is described in detail. FIG. 6 is a circuit diagram of the amplifier circuit 10C according to the fourth example. As illustrated in FIG. 6, the amplifier circuit 10C includes a signal input terminal 120, a signal output terminal 110, a carrier amplifier 11, a peak amplifier 21, phase shift lines 41 and 42, a splitter 50, a transformer 81, and a resistor element 75. The amplifier circuit 10C according to this example differs from the amplifier circuit 10A according to the second example in the connection configuration of the resistor element 75. Below, descriptions of configurations of the amplifier circuit 10C of this example identical to those of the amplifier circuit 10A of the second example are omitted, and different configurations are mainly described.

The resistor element 75 is an example of a first resistor element and is also an example of an impedance element. A first end of the resistor element 75 is connected to the second end of the coil 812 (the second terminal), and a second end of the resistor element 75 is connected to the first end of the coil 811 and the first end of the coil 812 (the first terminal). The resistor element 75 is connected in parallel with the coil 812.

In the amplifier circuit 10C according to this example, because a bypass route having the resistor element 75 is provided, the leakage of a signal from the peak amplifier 21 via the coils 812 and 811 to the signal output terminal 110 is offset by a signal transmitted through the bypass route. This in turn makes it possible to reduce the distortion of the output signal resulting from the operation of the peak amplifier 21.

A state of the amplifier circuit 10C according to this example is described in detail below with reference to FIG. 6.

As illustrated in FIG. 6, a radio frequency main signal is first input from the signal input terminal 120. Here, it is assumed that the phase of the radio frequency main signal is 0° at a node n1 on a path connecting the signal input terminal 120 to the splitter 50. It is also assumed that the power of the radio frequency main signal is distributed by the splitter 50 to a carrier main signal output to the carrier amplifier 11 and a peak signal and a peak auxiliary signal output to the peak amplifier 21. At a node n2 on a path connecting the splitter 50 to the carrier amplifier 11, the phase of the carrier main signal is unchanged at 0°. On the other hand, at a node n4 on a path connecting the phase shift line 41 to the peak amplifier 21, the phases of the peak signal and the peak auxiliary signal are delayed by the phase shift line 41 by 90° to become −90°.

Next, the phase of the carrier main signal is inverted by the carrier amplifier 11 and becomes −180° at a node n3 on a path connecting the output end of the carrier amplifier 11 to the coil 811. On the other hand, the phases of the peak signal and the peak auxiliary signal are inverted by the peak amplifier 21, become −270° at a node n5 corresponding to the output end of the peak amplifier 21, and are delayed by the phase shift line 42 by 90° to become 0° at a node n6 corresponding to the second end of the coil 812.

Next, the peak signal and the peak auxiliary signal amplified by the peak amplifier 21 diverge at the node n6. The peak signal reaches, via the coils 812 and 811, a node n7 on a path connecting the coil 811 to the signal output terminal 110. The peak auxiliary signal reaches the node n7 via the resistor element 75 and the coil 811. Here, because the peak signal passes through the coils 812 and 811 electromagnetically coupled to each other, the phase of the peak signal is inverted and becomes −180° at the node n7. On the other hand, because the peak auxiliary signal passes through the coil 812 and the resistor element 75 not electromagnetically coupled to each other, the phase of the peak auxiliary signal does not shift and is 0° at the node n7. That is, because the phases of the peak signal and the peak auxiliary signal are opposite to each other at the node n7, the peak signal and the peak auxiliary signal substantially offset each other at the node n7.

The resistance value of the resistor element 75 is determined such that the amplitudes of the peak signal and the peak auxiliary signal become substantially the same at the node n7.

This makes it possible to prevent a part of the output signal of the peak amplifier 21 from leaking to the signal output terminal 110 by itself. Thus, it is possible to provide the amplifier circuit 10C having improved power efficiency and configured to improve gain linearity and reduce signal distortion.

Here, in the amplifier circuit 10C according to this example, the resistor element 75 may be replaced with a first capacitor. The first capacitor is an example of an impedance element. A first end of the first capacitor is connected to the second end of the coil 812 (the second terminal), and a second end of the first capacitor is connected to the first end of the coil 811 and the first end of the coil 812 (the first terminal). The first capacitor is connected in parallel with the coil 812.

This makes it possible to prevent a part of the output signal of the peak amplifier 21 from leaking to the signal output terminal 110 by itself. Thus, it is possible to provide the amplifier circuit 10C having improved power efficiency and configured to improve gain linearity and reduce signal distortion.

### 1.7 Circuit Configuration of Amplifier Circuit 10D According to Fifth Example

Next, a circuit configuration of an amplifier circuit 10D according to a fifth example is described in detail. FIG. 7 is a circuit diagram of the amplifier circuit 10D according to the fifth example. As illustrated in FIG. 7, the amplifier circuit 10D includes a signal input terminal 120, a signal output terminal 110, a carrier amplifier 11, a peak amplifier 21, phase shift lines 41 and 42, a splitter 50, a transformer 81, and a capacitor 76. The amplifier circuit 10D according to this example differs from the amplifier circuit 10A according to the second example only in that the resistor element 73 is replaced with the capacitor 76. Below, descriptions of configurations of the amplifier circuit 10D of this example identical to those of the amplifier circuit 10A of the second example are omitted, and different configurations are mainly described.

The capacitor 76 is an example of a first capacitor and is also an example of an impedance element. A first end of the capacitor 76 is connected to the second end of the coil 812 (the second terminal), and a second end of the capacitor 76 is connected to the signal output terminal 110. The capacitor 76 is disposed in series in a bypass route different from a path connecting the second terminal, the coils 812 and 811, and the signal output terminal 110.

In the amplifier circuit 10D according to this example, because a bypass route having the capacitor 76 is provided, the leakage of a signal from the peak amplifier 21 via the transformer 81 to the signal output terminal 110 is offset by a signal transmitted through the bypass route. This in turn makes it possible to reduce the distortion of the output signal resulting from the operation of the peak amplifier 21.

A state of the amplifier circuit 10D according to this example is described in detail below with reference to FIG. 7.

As illustrated in FIG. 7, the peak signal and the peak auxiliary signal amplified by the peak amplifier 21 diverge at the second end of the coil 812. The peak signal reaches, via the coils 812 and 811, a node n7 on a path connecting the coil 811 to the signal output terminal 110. The peak auxiliary signal reaches the node n7 via the capacitor 76. Here, because the peak signal is transmitted from the second end of the coil 812 to the second end of the coil 811, the phase of the peak signal is inverted and becomes −180° at the node n7. On the other hand, because the peak auxiliary signal passes through the capacitor 76, the phase of the peak auxiliary signal does not shift and is 0° at the node n7. That is, because the phases of the peak signal and the peak auxiliary signal are opposite to each other at the node n7, the peak signal and the peak auxiliary signal substantially offset each other at the node n7.

The capacitance of the capacitor 76 is determined such that the amplitudes of the peak signal and the peak auxiliary signal become substantially the same at the node n7.

This makes it possible to prevent a part of the output signal of the peak amplifier 21 from leaking to the signal output terminal 110 by itself. Thus, it is possible to provide the amplifier circuit 10D having improved power efficiency and configured to improve gain linearity and reduce signal distortion.

### 2. Effects

As described above, each of the amplifier circuit 10 according to the first example, the amplifier circuit 10A according to the second example, and the amplifier circuit 10D according to the fifth example includes the signal input terminal 120, the signal output terminal 110, the carrier amplifier 11, the peak amplifier 21, the phase shift line 42, the power combiner that combines radio frequency signals input to the first terminal and the second terminal to obtain a combined radio frequency signal and outputs the combined radio frequency signal from the third terminal, and an impedance element that is a resistor element or a capacitor. The carrier amplifier 11 is connected between the signal input terminal 120 and the first terminal, the peak amplifier 21 is connected between the signal input terminal 120 and the first end of the phase shift line 42, the second end of the phase shift line 42 is connected to the second terminal, the signal output terminal 110 is connected to the third terminal, the first end of the impedance element is connected to the second terminal, and the second end of the impedance element is connected to the signal output terminal 110.

With this configuration, because a bypass route having the impedance element is provided, the leakage of a signal from the peak amplifier 21 via the power combiner to the signal output terminal 110 is offset by a signal transmitted through the bypass route. This in turn makes it possible to reduce the distortion of the output signal resulting from the operation of the peak amplifier 21. Thus, it is possible to provide the amplifier circuits 10, 10A, and 10D having improved power efficiency and configured to improve gain linearity and reduce signal distortion.

Also, for example, in the amplifier circuits 10, 10A, and 10D, each of the carrier amplifier 11 and the peak amplifier 21 is an inverting amplifier, and the phase shift line 42 is a phase shift line that delays an input signal by 90°.

This makes it possible to provide the Doherty amplifier circuits 10, 10A, and 10D with improved efficiency in the low output power region and improved linearity in the high output power region.

Also, for example, in the amplifier circuit 10, the power combiner is the transformer 80 including the coils 801 and 802, the first end of the coil 801 is connected to the first terminal, the second end of the coil 801 is connected to the second terminal, the first end of the coil 802 is connected to the third terminal, and the second end of the coil 802 is connected to the ground.

This makes it possible to provide the amplifier circuit 10 having improved power efficiency and configured to reduce signal distortion.

Also, for example, in the amplifier circuits 10A and 10D, the power combiner is the transformer 81 including the coils 811 and 812, the first end of the coil 811 and the first end of the coil 812 are connected to the first terminal, the second end of the coil 812 is connected to the second terminal, and the second end of the coil 811 is connected to the third terminal.

This makes it possible to provide the amplifier circuits 10A and 10D having improved power efficiency and configured to reduce signal distortion.

Also, the amplifier circuit 10B according to the third example includes the signal input terminal 120, the signal output terminal 110, the carrier amplifier 11, the peak amplifier 21, the phase shift line 42, the power combiner that combines radio frequency signals input to the first terminal and the second terminal to obtain a combined radio frequency signal and outputs the combined radio frequency signal from the third terminal, and an impedance element that is a resistor element or a capacitor. The carrier amplifier 11 is connected between the signal input terminal 120 and the first terminal, the peak amplifier 21 is connected between the signal input terminal 120 and the first end of the phase shift line 42, the second end of the phase shift line 42 is connected to the second terminal, the signal output terminal 110 is connected to the third terminal, the first end of the impedance element is connected to the first terminal, and the second end of the impedance element is connected to the signal output terminal 110.

With this configuration, because a bypass route having the impedance element is provided, the leakage of a signal from the peak amplifier 21 via the power combiner to the signal output terminal 110 is offset by a signal transmitted through the bypass route. This in turn makes it possible to reduce the distortion of the output signal resulting from the operation of the peak amplifier 21. Thus, it is possible to provide the amplifier circuit 10B having improved power efficiency and configured to improve gain linearity and reduce signal distortion.

Also, for example, in the amplifier circuit 10B, each of the carrier amplifier 11 and the peak amplifier 21 is an inverting amplifier, and the phase shift line 42 is a phase shift line that delays an input signal by 90°.

This makes it possible to provide the Doherty amplifier circuit 10B with improved efficiency in the low output power region and improved linearity in the high output power region.

Also, for example, in the amplifier circuit 10B, the power combiner is the transformer 81 including the coils 811 and 812, the first end of the coil 811 and the first end of the coil 812 are connected to the first terminal, the second end of the coil 812 is connected to the second terminal, and the second end of the coil 811 is connected to the third terminal.

This makes it possible to provide the amplifier circuit 10B having improved power efficiency and configured to reduce signal distortion.

Also, the amplifier circuit 10C according to the fourth example includes the signal input terminal 120, the signal output terminal 110, the carrier amplifier 11, the peak amplifier 21, the phase shift line 42, the power combiner that combines radio frequency signals input to the first terminal and the second terminal to obtain a combined radio frequency signal and outputs the combined radio frequency signal from the third terminal, and an impedance element that is a resistor element or a capacitor. The carrier amplifier 11 is connected between the signal input terminal 120 and the first terminal, the peak amplifier 21 is connected between the signal input terminal 120 and the first end of the phase shift line 42, the second end of the phase shift line 42 is connected to the second terminal, the signal output terminal 110 is connected to the third terminal, the first end of the impedance element is connected to the second terminal, and the second end of the impedance element is connected to the first terminal.

With this configuration, because a bypass route having the impedance element is provided, the leakage of a signal from the peak amplifier 21 via the power combiner to the signal output terminal 110 is offset by a signal transmitted through the bypass route. This in turn makes it possible to reduce the distortion of the output signal resulting from the operation of the peak amplifier 21. Thus, it is possible to provide the amplifier circuit 10C having improved power efficiency and configured to improve gain linearity and reduce signal distortion.

Also, for example, in the amplifier circuit 10C, each of the carrier amplifier 11 and the peak amplifier 21 is an inverting amplifier, and the phase shift line 42 is a phase shift line that delays an input signal by 90°.

This makes it possible to provide the Doherty amplifier circuit 10C with improved efficiency in the low output power region and improved linearity in the high output power region.

Also, for example, in the amplifier circuit 10C, the power combiner is the transformer 81 including the coils 811 and 812, the first end of the coil 811 and the first end of the coil 812 are connected to the first terminal, the second end of the coil 812 is connected to the second terminal, and the second end of the coil 811 is connected to the third terminal.

This makes it possible to provide the amplifier circuit 10C having improved power efficiency and configured to reduce signal distortion.

For example, each of the amplifier circuits 10, 10A, 10B, 10C, and 10D further includes the splitter 50 connected between the signal input terminal 120 and the input ends of the carrier amplifier 11 and the peak amplifier 21, and the phase shift line 41 connected between the signal input terminal 120 and the input end of the peak amplifier 21.

This makes it possible to divide an input radio frequency signal into two radio frequency signals that have a predetermined phase difference.

Also, for example, in the amplifier circuits 10, 10A, 10B, 10C, and 10D, the phase shift line 41 is a phase shift line that delays an input signal by 90°.

This makes it possible to divide an input radio frequency signal into two radio frequency signals that have a phase difference of 90°.

### Other Embodiments

Amplifier circuits according to the examples of the exemplary embodiment of the present disclosure are described above. However, the present disclosure is not limited to the above described examples. The present disclosure also includes other examples implemented by combining components in the above examples, variations obtained by applying various modifications conceivable by a person skilled in the art to the above examples within the scope of the present disclosure, and various devices including the above-described amplifier circuits.

Also, for example, in the amplifier circuits, the radio frequency circuit, and the communication device according to the above examples, another component, such as a circuit element or a wire, may be inserted in paths connecting circuit elements and signal paths disclosed in the figures.

Below, features of the amplifier circuits according to the above examples are described.

<1> An amplifier circuit includes an input terminal and an output terminal; a carrier amplifier and a peak amplifier; a first phase shift circuit; a power combiner that combines radio frequency signals input to a first terminal and a second terminal to obtain a combined radio frequency signal and outputs the combined radio frequency signal from a third terminal; and an impedance element that is a resistor element or a capacitor. The carrier amplifier is connected between the input terminal and the first terminal; the peak amplifier is connected between the input terminal and a first end of the first phase shift circuit; a second end of the first phase shift circuit is connected to the second terminal; the output terminal is connected to the third terminal; a first end of the impedance element is connected to the second terminal; and a second end of the impedance element is connected to the output terminal.

<2> The amplifier circuit described in <1>. Each of the carrier amplifier and the peak amplifier is an inverting amplifier; and the first phase shift circuit is a phase shift line that delays an input signal by 90°.

<3> The amplifier circuit described in <1> or <2>. The power combiner is a transformer including a first coil and a second coil; a first end of the first coil is connected to the first terminal; a second end of the first coil is connected to the second terminal; a first end of the second coil is connected to the third terminal; and a second end of the second coil is connected to a ground.

<4> The amplifier circuit described in <1> or <2>. The power combiner is a transformer including a first coil and a second coil; a first end of the first coil and a first end of the second coil are connected to the first terminal; a second end of the first coil is connected to the second terminal; and a second end of the second coil is connected to the third terminal.

<5> An amplifier circuit includes an input terminal and an output terminal; a carrier amplifier and a peak amplifier; a first phase shift circuit; a power combiner that combines radio frequency signals input to a first terminal and a second terminal to obtain a combined radio frequency signal and outputs the combined radio frequency signal from a third terminal; and an impedance element that is a resistor element or a capacitor. The carrier amplifier is connected between the input terminal and the first terminal; the peak amplifier is connected between the input terminal and a first end of the first phase shift circuit; a second end of the first phase shift circuit is connected to the second terminal; the output terminal is connected to the third terminal; a first end of the impedance element is connected to the first terminal; and a second end of the impedance element is connected to the output terminal.

<6> The amplifier circuit described in <5>. Each of the carrier amplifier and the peak amplifier is an inverting amplifier; and the first phase shift circuit is a phase shift line that delays an input signal by 90°.

<7> The amplifier circuit described in <5> or <6>. The power combiner is a transformer including a first coil and a second coil; a first end of the first coil and a first end of the second coil are connected to the first terminal; a second end of the first coil is connected to the second terminal; and a second end of the second coil is connected to the third terminal.

<8> An amplifier circuit includes an input terminal and an output terminal; a carrier amplifier and a peak amplifier; a first phase shift circuit; a power combiner that combines radio frequency signals input to a first terminal and a second terminal to obtain a combined radio frequency signal and outputs the combined radio frequency signal from a third terminal; and an impedance element that is a resistor element or a capacitor. The carrier amplifier is connected between the input terminal and the first terminal; the peak amplifier is connected between the input terminal and a first end of the first phase shift circuit; a second end of the first phase shift circuit is connected to the second terminal; the output terminal is connected to the third terminal; a first end of the impedance element is connected to the second terminal; and a second end of the impedance element is connected to the first terminal.

<9> The amplifier circuit described in <8>. Each of the carrier amplifier and the peak amplifier is an inverting amplifier; and the first phase shift circuit is a phase shift line that delays an input signal by 90°.

<10> The amplifier circuit described in <8> or <9>. The power combiner is a transformer including a first coil and a second coil; a first end of the first coil and a first end of the second coil are connected to the first terminal; a second end of the first coil is connected to the second terminal; and a second end of the second coil is connected to the third terminal.

<11> The amplifier circuit described in any one of <1> to <10> further includes a power splitter connected between the input terminal and input ends of the carrier amplifier and the peak amplifier; and a second phase shift circuit connected between the input terminal and the input end of the peak amplifier.

<12> The amplifier circuit described in <11>. The second phase shift circuit is a phase shift line that delays an input signal by 90°.

The present disclosure can be widely used for communication devices, such as mobile phones, as an amplifier circuit disposed in a multiband front-end unit.

What is claimed is:

1. An amplifier circuit comprising:
an input terminal and an output terminal;
a carrier amplifier and a peak amplifier;
a first phase shift circuit;
a power combiner that combines radio frequency signals input to a first terminal and a second terminal to obtain a combined radio frequency signal and outputs the combined radio frequency signal from a third terminal; and
an impedance element, wherein
the carrier amplifier is connected between the input terminal and the first terminal;
the peak amplifier is connected between the input terminal and a first end of the first phase shift circuit;
a second end of the first phase shift circuit is connected to the second terminal;
the output terminal is connected to the third terminal;
a first end of the impedance element is connected to the second terminal; and
a second end of the impedance element is connected to the output terminal.

2. The amplifier circuit according to claim 1, wherein the impedance element includes a resister element or a capacitor.

3. The amplifier circuit according to claim 1, wherein
each of the carrier amplifier and the peak amplifier is an inverting amplifier; and
the first phase shift circuit is a phase shift line that delays an input signal by 90°.

4. The amplifier circuit according to claim 1, wherein
the power combiner is a transformer including a first coil and a second coil;
a first end of the first coil is connected to the first terminal;
a second end of the first coil is connected to the second terminal;
a first end of the second coil is connected to the third terminal; and
a second end of the second coil is connected to a ground.

5. The amplifier circuit according to claim 1, wherein
the power combiner is a transformer including a first coil and a second coil;
a first end of the first coil and a first end of the second coil are connected to the first terminal;
a second end of the first coil is connected to the second terminal; and
a second end of the second coil is connected to the third terminal.

6. The amplifier circuit according to claim 1, further comprising:
a power splitter connected between the input terminal and input ends of the carrier amplifier and the peak amplifier; and
a second phase shift circuit connected between the input terminal and the input end of the peak amplifier.

7. The amplifier circuit according to claim 6, wherein
the second phase shift circuit is a phase shift line that delays an input signal by 90°.

8. An amplifier circuit comprising:
an input terminal and an output terminal;
a carrier amplifier and a peak amplifier;
a first phase shift circuit;
a power combiner that combines radio frequency signals input to a first terminal and a second terminal to obtain a combined radio frequency signal and outputs the combined radio frequency signal from a third terminal; and
an impedance element, wherein
the carrier amplifier is connected between the input terminal and the first terminal;
the peak amplifier is connected between the input terminal and a first end of the first phase shift circuit;
a second end of the first phase shift circuit is connected to the second terminal;
the output terminal is connected to the third terminal;
a first end of the impedance element is connected to the first terminal; and
a second end of the impedance element is connected to the output terminal.

9. The amplifier circuit according to claim 8, wherein the impedance element includes a resister element or a capacitor.

10. The amplifier circuit according to claim 8, wherein
each of the carrier amplifier and the peak amplifier is an inverting amplifier; and
the first phase shift circuit is a phase shift line that delays an input signal by 90°.

11. The amplifier circuit according to claim 8, wherein
the power combiner is a transformer including a first coil and a second coil;
a first end of the first coil and a first end of the second coil are connected to the first terminal;
a second end of the first coil is connected to the second terminal; and
a second end of the second coil is connected to the third terminal.

12. The amplifier circuit according to claim 8, further comprising:
a power splitter connected between the input terminal and input ends of the carrier amplifier and the peak amplifier; and
a second phase shift circuit connected between the input terminal and the input end of the peak amplifier.

13. The amplifier circuit according to claim 12, wherein
the second phase shift circuit is a phase shift line that delays an input signal by 90°.

14. An amplifier circuit comprising:
an input terminal and an output terminal;
a carrier amplifier and a peak amplifier;
a first phase shift circuit;
a power combiner that combines radio frequency signals input to a first terminal and a second terminal to obtain a combined radio frequency signal and outputs the combined radio frequency signal from a third terminal; and
an impedance element, wherein
the carrier amplifier is connected between the input terminal and the first terminal;
the peak amplifier is connected between the input terminal and a first end of the first phase shift circuit;
a second end of the first phase shift circuit is connected to the second terminal;
the output terminal is connected to the third terminal;
a first end of the impedance element is connected to the second terminal; and
a second end of the impedance element is connected to the first terminal.

15. The amplifier circuit according to claim 14, wherein the impedance element includes a resister element or a capacitor.

16. The amplifier circuit according to claim 14, wherein
each of the carrier amplifier and the peak amplifier is an inverting amplifier; and
the first phase shift circuit is a phase shift line that delays an input signal by 90°.

17. The amplifier circuit according to claim 14, wherein
the power combiner is a transformer including a first coil and a second coil;
a first end of the first coil and a first end of the second coil are connected to the first terminal;
a second end of the first coil is connected to the second terminal; and
a second end of the second coil is connected to the third terminal.

18. The amplifier circuit according to claim 14, further comprising:
a power splitter connected between the input terminal and input ends of the carrier amplifier and the peak amplifier; and
a second phase shift circuit connected between the input terminal and the input end of the peak amplifier.

19. The amplifier circuit according to claim 18, wherein
the second phase shift circuit is a phase shift line that delays an input signal by 90°.
